(19) United States
(12) Patent Application Publication
(10) Pub. No.: US 2010/0039683 A1
(43) Pub. Date: Feb. 18, 2010

(54) SCANNING METHOD AND AUXILIARY APPARATUS OF AUTO-EXECUTING APPENDING SCANNING FUNCTION

(75) Inventor: Kui Lv, Suzhou City (CN)

Correspondence Address: COVENANT IP CONSULTING CO., P.O. BOX 34-306 TAIPEI CITY, TAIPEI, 10499, TW

(73) Assignee: Qisda (SuZhou) Co., ltd, Suzhou (CN)

(21) Appl. No.: 12/505,488

(22) Filed: Jul. 19, 2009

(30) Foreign Application Priority Data
Aug. 15, 2008 (CN) 200810021163.2

(51) Int. Cl. G03F 3/08; H04N 1/40

(52) U.S. Cl. 358/518; 358/448

(57) ABSTRACT

A scanning method and an auxiliary apparatus of auto-executing appended scanning function are disclosed. A specific image, which can be identified by a scanning module of a scanning device, is first loaded on a scanned document or a scanned document carrier, and an appended function denoted by the specific image is predetermined in a processing module of the scanning device. Then, as the scanning device scans the scanned document or the scanned document carrier with the specific image, the scanning device automatically executes the predetermined appended scanning function or processing function according to the scan data of the specific image. The invention can be applied to all kinds of portable scanning device, and especially can be applied to small-sized portable scanning devices for scanning photos, name cards, and so on to realize the direct display and connection with a display device or a storage device.

This application claims the benefit of China application Serial No. 200810021163.2, filed Aug. 15, 2008, the subject matter of which is incorporated herein by reference.

### BACKGROUND OF THE INVENTION

1. Field of the Invention

The invention relates in general to a scanning method and the technology of scanning device, and more particularly to a scanning method of automatically executing multiple appended scanning functions and an auxiliary apparatus thereof.

2. Description of the Related Art

Scanning device is a widely used electronic input device and has a scanning module used for acquiring the image data of a scanned document and converting the image data into an electronic file. Currently, there is a large variety of scanning device available in the market. Examples of the scanning device include large-sized scanning devices used for scanning documents and small-sized portable scanning devices used for scanning photos or name cards. In terms of the small-sized portable scanning devices, for user's convenience in use, the design of the scanning device is as simple as possible, and only one function key is provided so as to meet the user's expectation of executing all kinds of functions of the scanning device through simple operation.

For a scanning device to execute an application other than ordinary functions, normally an electronic device such as a computer which is connected to the scanning device and has processing software is needed. Examples of the application function include adjusting RGB color of a scanned image, adding filtering effect to an image or setting a specific scan boundary. For an application function to be executed on the scanning device, additional hardware design is needed. Through the added hardware design, the user can select the appended especial scanning functions and then the scanning device executes related functions according to the user's setting. The scanning device requires corresponding man-machine interfaces to implement the added hardware design. Examples of the man-machine interfaces include several keys and a combination of touch control and keys of LCD screen. Such design is more costive and the scanning device will become bigger in size and affect its portability. Furthermore, as the user has to go through several operation steps, the user will find it inconvenient in use.

### SUMMARY OF THE INVENTION

The invention is directed to a scanning method and an auxiliary apparatus of auto-executing an appended scanning function of a scanning device without using any additional design in external display or keys of the scanning device, hence simplifying user's operation. The invention achieves the goal of appending multi-function of the scanning device without incurring additional design cost, and at the same time effectively extends the application of related products.

The technology adopted in the invention is stated below.

A scanning method of automatically executing appended scanning or processing function of a scanning device includes the steps stated below.

A specific image, which can be identified by a scanning module of the scanning device, is loaded on a scanned document or a scanned document carrier, and an appended function denoted by the specific image is predetermined in a processing module of the scanning device; and

As the scanning device scans the scanned document or the scanned document carrier with the specific image, the scanning device automatically executes the predetermined appended scanning function or processing function according to the scan data of the specific image.

To put the scanning method in greater details, the scanning method further includes:

A determination region is disposed at a scan initial end of a scanned document or a scanned document carrier. The specific image is located within the determination region. The scanning module of the scanning device, first of all, scans the determination region, and automatically executes the predetermined appended function according to the scan data of the specific image obtained in the determination region.

The specific image, which can be identified by a scanning device, is a barcode type image, a black dot-formed image, a white dot-formed image, a black-and-white image, a color image, or a combined image of the above images.

The scanning method further includes:

As the scanning device scans the specific image, a fixed number of lines is scanned first so as to obtain the scan data of the specific image including a combined data of the black and the white of the scanned image or an interval data of the scan data;

The black color and the white color are defined as a default value range of the scanning device; and

The scanning device compares the scan data of the specific image with the predetermined data to confirm the appended scanning function denoted by the scan data of the specific image, and then executes the appended scanning function for scanning or processing the scanned document.

The predetermined appended function includes the scanning functions of confirming a scan boundary and setting clarity level, and the image-processing functions of calibrating and adjusting a scanned image.

Another scanning method of automatically executing appended scanning function includes the steps stated below.

A determination region is allocated at a scan initial end of a scanned document or a scanned document carrier. A specific image, which can be identified by a scanning module of a scanning device, is loaded on the determination region. The specific image, which can be identified by the scanning device, is a barcode type image, a black dot-formed image, a white dot-formed image, a black-and-white image, a color image, or a combined image of the above images;

The appended scanning or processing function corresponding to the scan data of the specific image is predetermined in a processing module of the scanning device; and

As the scanning device begins scanning, the determination region is first scanned to obtain the scan data of the specific image. Then, the appended scanning or processing function denoted by the scan data is automatically executed.

The scan data of the specific image includes a digit string. The predetermined appended scanning function or processing function is recorded in the scanning device as an algorithm or a program.

An auxiliary apparatus of auto-executing appended scanning function includes:

A determination region, wherein a specific image, which can be identified by a scanning module of a scanning device is loaded on the determination region; and

A scan region used for disposing a to-be-scanned region of a scanned document.

The auxiliary apparatus is a planar structure, wherein the scan initial end of the planar structure is a determination region, and a specific image is printed, placed or pasted on the determination region, and a scan end side of the scan region has a transparent scan storing portion used for fixing the scanned document.

The determination region has a transparent storage bag for retaining the specific image or a transparent sheet whose partial edge is fixed with the auxiliary apparatus.

According to the scanning method of automatically executing appended scanning function, a specific image is disposed on a scanned document as a specific tag, and the scan data of the tag is used as a basis for determining the application function used for scanning the subsequent image. The appended function can be an appended scanning function or an appended image-processing function other than ordinary scanning functions. Examples of the appended function includes setting a boundary when trimming a scanned document, selecting a rotation angle of an image, selecting the scan features such as the scan mode (color scan or black-and-white scan) and the clarity level. Examples of the image processing function include calibrating, adjusting or filtering a scanned image.

The specific image can be all kinds of images or image combination which can be identified by a scanning device. The specific image preferably is an image which can be scanned correctly. For example, the specific image can be a barcode type image, a black dot-formed image, a white dot-formed image, a black-and-white image, a color image, or a combined image of the above images. The specific image formed by a color image can be identified by a scanning device by way of binarization. For example, the identification between black and white by the scanning device is defined as a value predetermined in a program, the color is identified as white if the scan value is larger than the predetermined value, and the color is identified as black if the scan value is smaller than the predetermined value. The predetermined value can also be defined as a range to fit actual needs. The barcode type image has a diversity of combination so as to completely denote all kinds of scanning functions, image-processing functions or a combination thereof. The combination of black dots, white dots or black and white dots, also having a diversified range of variety. For example, by controlling the distance of the black dots or the white dots or the intervals between different black-and-white dots, different appended functions can also be defined. The specific image, formed by printing, pasting or attaching, can be scanned together with the scanned document. The appended function denoted by the specific image is predetermined in a processing module of the scanning device.

When the scanning device begins scanning, the specific image is first scanned. For the specific image and the scanned document to be properly combined, a determination region is allocated at a scan initial end of the scanned document or a scanned document carrier, wherein the specific image is located within the determination region, and the determination region does not block or cover the to-be-scanned region of the scanned document. If the scanned document permits, the determination region can be directly disposed on the scanned document. If the non-scan region of the scanned document is too small to have the determination region disposed thereon, the scanned document carrier is used and the scanned document is placed on the scanned document carrier, and the determination region is disposed on the scanned document carrier at the same time. The specific image is located within the determination region. The scanning device first scans the determination region and obtains a scan data of the specific image. Then, the scanning device compares the scan data with the scan data of each predetermined appended function. If the scan data of the specific image matches with the scan data of the appended function, the scanning device directly calls the appended function, and automatically executes the appended function in the subsequent scanning or processing of the scanned document. Lastly, the scan data processed by the appended function is directly obtained.

The scan data of the specific image can be a digital signal such as a digit string for example. Through the predetermined number of lines to be scanned, the scanning device obtains the scan data of the specific image, that is, a set of digit string, used for being compared with the scan data predetermined in the scanning device.

When the appended scanning function is performed according to the scanning method, complicated operation and multiple steps via multiple key on the scanning device are avoided. Therefore, the scanning device dispenses with the need for all kinds of expensive design of man-machine-interfaces, not only reducing the cost of the scanning device but also reducing the volume of the scanning device and improving the portability of the scanning device. A user only need to place the scanned document on the scanned document carrier denoting the appended function being required or place a specific image of the appended function being required on the not-to-be-scanned region of the scanned document, then the scanning device will automatically complete scanning based on the appended function.

The auxiliary apparatus of auto-executing appended scanning function is a scanned document carrier for placing a scanned document or a scanned document having a determination region. The auxiliary apparatus is, for example, a planar structure which can be fed into the scanning device, wherein the planar structure, having a determination region and a scan region, can be formed by different universal structures. The auxiliary apparatus preferably adopts a planar structure as the carrier body, wherein a determination region is disposed at the front end of the carrier body and a scan region is disposed at the rear end of the carrier body. A specific image is printed, placed or pasted on the determination region. For example, a transparent sheet, such as a transparent bag or a transparent film whose partial edge is fixed with the carrier body, can be used for loading with the specific image, so that the specific image will not move during sheet-fed scanning and the scan data will be correctly obtained. The scanned document is preferably fixed in the scan region through the transparent bag or the transparent film structure so that the scanned document can be well separated from the auxiliary apparatus. The determination region of the auxiliary apparatus can have many different specific images printed thereon. The scanning device can work with a set of several auxiliary apparatuses, and the user can select a suitable auxiliary apparatus for scanning according to the required function, or use one carrier body to work with a printing sheet having a set of different specific images.

The scanning method and the auxiliary apparatus of auto-executing appended scanning function achieve the goal of appending multi-functions and incurring low manufacturing cost with the help of a specific image of a predetermined appended function, so the scanning device is more portable and small sized as well as provides various appended scanning functions and image-processing functions. The invention can be used to realize the appended functions in all kinds of portable scanning device such as sheet-fed scanning device. Particularly, the invention can be used to expand the function of a small-sized portable scanning device for scanning photos or name cards so as to realize the direct display and connection with a display device or a storage device.

The invention will become apparent from the following detailed description of the preferred but non-limiting embodiments. The following description is made with reference to the accompanying drawings.

### BRIEF DESCRIPTION OF THE DRAWINGS

FIG. 1 shows a flowchart of a scanning method according to an embodiment of the invention;

FIG. 2 shows a detailed flowchart of a scanning method according to an embodiment of the invention; and

FIGS. 3 to 6 show structural diagrams of different auxiliary apparatuses each according to an embodiment of the invention.

### DETAILED DESCRIPTION OF THE INVENTION

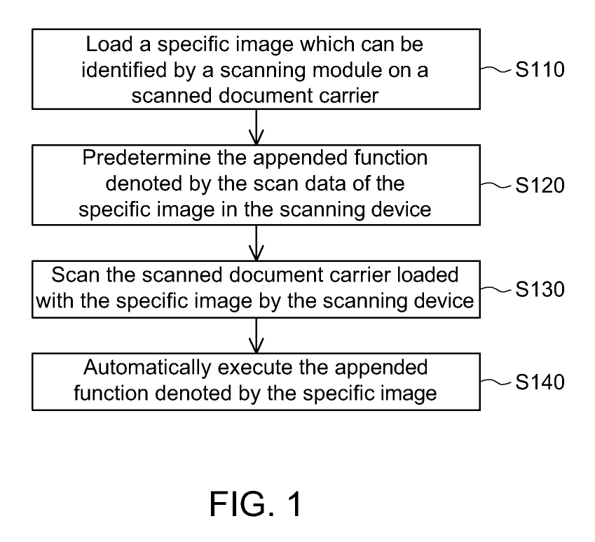

As indicated in FIG. 1, the scanning method of automatically executing appended scanning function can be implemented by a portable scanning device. The method begins at step S110, a specific image which can be identified by a scanning module is loaded on a scanned document carrier, wherein the specific image preferably is a barcode which can be correctly identified by the scanning module. Next, the method proceeds to step S120, the scan data of the specific image constituted by the barcode is predetermined as a tag of an appended function in the scanning device. After the scan data of the specific image is obtained by the scanning device, the appended function denoted by the scan data is automatically executed. Then, the method proceeds to step S130, the scanned document carrier loaded with the specific image is scanned by the scanning device and the scan data of the specific image is obtained by the scanning device, wherein the specific image is scanned before the scanned document. After that, the scanning device compares the scan data of the specific image with the scan data predetermined in the scanning device, and executes step S140, the appended function denoted by the specific image is automatically executed.

The appended function can be a specific setting of a scan boundary. For example, if only the image of a scan range of a document is needed, the appended function is added so that the scanned document is trimmed according to the specific image denoting the scan boundary. The appended function can be the rotation of an image. For example, the image of a photo being scanned has to be rotated for 90 degrees or other angles before the image can be directly and correctly displayed on a digital frame or an electronic device. With the arrangement of different specific images, several different appended functions can be executed by the scanning device. The appended function can further be an image-processing function of filtering or processing a scanned image of the scanned document.

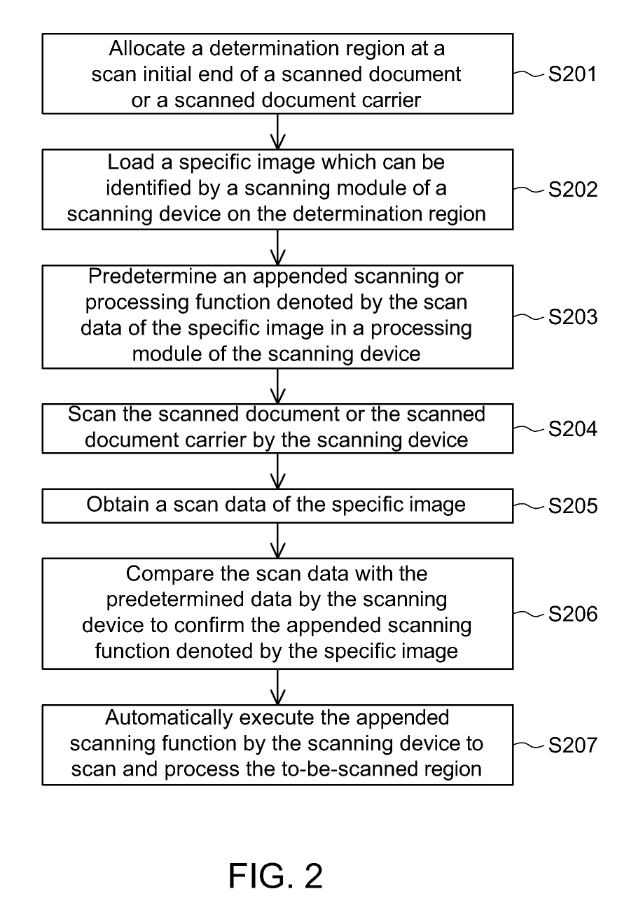

FIG. 2 shows a detailed flowchart of a scanning method according to an embodiment of the invention. The method begins at step S201, a determination region is allocated at a scan initial end of a scanned document or a scanned document carrier, wherein the determination region is a scannable region occupies only a small area. For a scanned document having a certain scan edge, the determination region can be allocated at the edge of a to-be-scanned region. For the scanned document carrier, the determination region is a scannable region allocated at an end of the scanned document carrier. Next, the method proceeds to step S202, a specific image which can be identified by a scanning module of a scanning device is loaded on the determination region. The specific image can be a barcode or a combined image of black dots or white dots distributed in the black area. The specific image provides the scanning device with a specific and accurate scan data. The specific image, being made from a piece of paper or other printable sheet, can be directly pasted on the determination region for scanning. The specific image can also be directly placed on the scanned document carrier. A transparent bag for loading with the specific image or a transparent sheet whose edge is partially fixed with the determination region is fixed on the scanned document carrier, and since the specific image is directly placed in the transparent bag or the transparent sheet, the scan data can be correctly obtained. Then, the method proceeds to step S203, an appended scanning or processing function denoted by the scan data of the specific image is predetermined in a processing module of the scanning device. The appended function can be recorded in the scanning device as an algorithm or an executable program, so that the added multiple appended function will not occupy any space of the scanning device.

After that, the method proceeds to step S204, the scanned document or the scanned document carrier is scanned by the scanning device, wherein the determination region is scanned first. Afterwards, the method proceeds to step S205, a scan data of the specific image is obtained. Then, the method proceeds to step S206, the scan data is compared with the predetermined data by the scanning device to confirm the appended scanning function denoted by the specific image.

After that, the method proceeds to step S207, the appended scanning function is automatically executed by the scanning device to scan and process the to-be-scanned region. The appended function can be the function of adjusting a scanned image. For example, the scanned document is a black-and-white and old photo whose basic color already fades, and the adjusting function is used for removing the faded basic color, so that the image becomes clearer. The appended function can further be a combination of a calibrating function and a clarity setting function.

During the entire scanning process, a user only needs to select a scanned document carrier or a determination region, for the instance that when a sheet with a specific image is disposed on the scanned document, corresponding to the user's own needs, the scanning device will automatically execute the appended function being selected to obtain an image data with processed effect which can be directly displayed on a digital frame or stored in another display device.

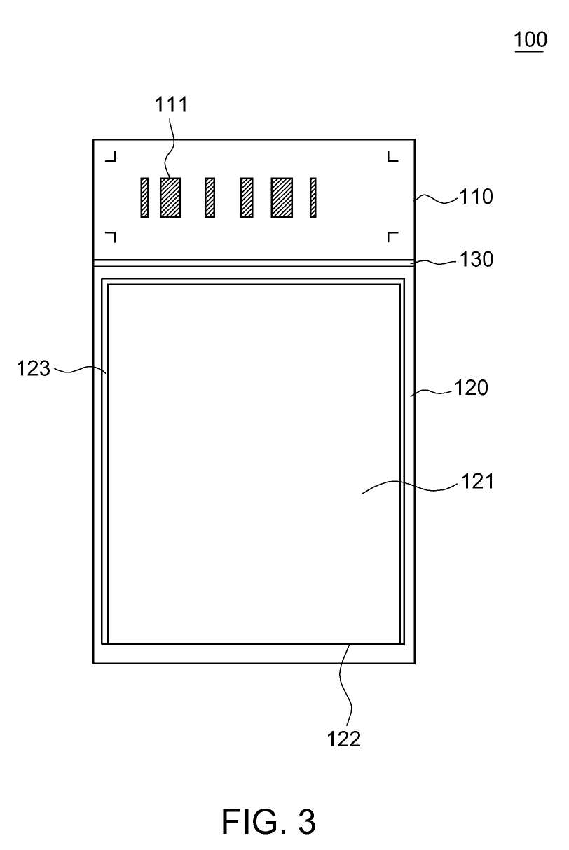

FIG. 3 shows a structural diagram of an auxiliary apparatus 100 according to an embodiment of the invention. The auxiliary apparatus 100 includes a determination region 110 and a scan region 120, and the entire body of the auxiliary apparatus 100 is a paper sheet whose width is approximately equal to the maximum scanning span of the scanning device and is applicable to both sheet-fed type scanning and static type scanning. A narrower region at the front end of the auxiliary apparatus 100 is used as the determination region 110. A specific image, formed by a barcode 111, is printed on the determination region 110, wherein the appended function denoted by the specific image is that the scanned image must be rotated for 90 degree clock-wise after scanned. The scan region 120 is located at the rear end of the auxiliary apparatus 100. The scan region 120 is used for loading with a scanned document. A transparent film 121, pasted on the scan region 120, has three edges including the left edge 123 attached to the scan region. The transparent film 121 and the scan region 120 form a transparent bag that has an opening 122 facing toward the rear end of the auxiliary apparatus 100. The scanned document can be directly placed in the bag constituted by the transparent film 121 and the scan region 120, so that the scanned document does not move relatively to the auxiliary apparatus when being scanned. The transparency of the transparent film 121 does not affect the image scanning.

The scanning device can automatically adjust the initial scan point of a scanned document according to the positions of the specific image and the scan region. With a boundary region which can be identified by way of scanning being disposed between the determination region and the scan region, the appended function can also be realized. After the scanning device scans the barcode 111 of the determination region 110, the scanning device automatically executes the appended function of rotating the scanned image of the scanned document for 90 degrees so that the scanned image of the scanned document can be directly and correctly displayed on a digital frame or a display device or directly stored in an electronic device without using a complicated external hardware such as a computer or using a large-scale software to rotate the scanned image. Thus, the expansion of the appended function of the scanning device and the operation of the user are made easier and simpler.

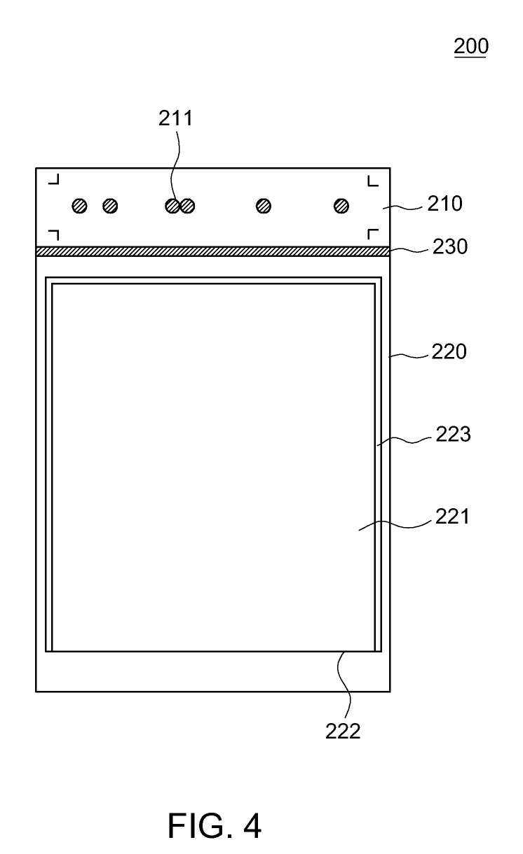

FIG. 4 shows a structural diagram of an auxiliary apparatus 200 according to an embodiment of the invention. The auxiliary apparatus 200 is constituted mainly by a determination region 210 and a scan region 220, and the entire body of the auxiliary apparatus 200 is a flexible plastic sheet whose front end has the determination region 210. A specific image constituted by black dots 211 is printed on the determination region 210, wherein the intervals and the number of the black dots are the main comparison data for scanning and identification, and the appended function denoted by the specific image is used for filtering the image of the scan region 220 to eliminate the scratches on the face or other part of the people on the photo or the scanned document placed on the scan region 220. The scan region 220 is located at the rear end of the auxiliary apparatus 200 for loading with the scanned document. A transparent bag 221, whose opening 222 faces toward to the rear end, is fixed within the scan region 220, and an edge 223 of the bag is, for example, adhered to the scan region 220. The photo scanned document can be placed in the transparent bag 221 for the appended function.

After a scanning device begins scanning, the determination region 210 of the auxiliary apparatus used as an initial scan end is loaded into the scanning device. The specific image constituted by the black dots 211 of the determination region 210 is scanned by the scanning device first, for example, the scan data of various scan lines is obtained by scanning the determination region according to the predetermined 16-line scan format. Then, the scan data is compared with the content predetermined in a processing module of the scanning device to check if the appended filtering function is to be executed. Then, the scanning device continues to scan the scanned document and automatically executes the appended function, so as to directly obtain and output the scan data of the scanned document on which the appended function is executed.

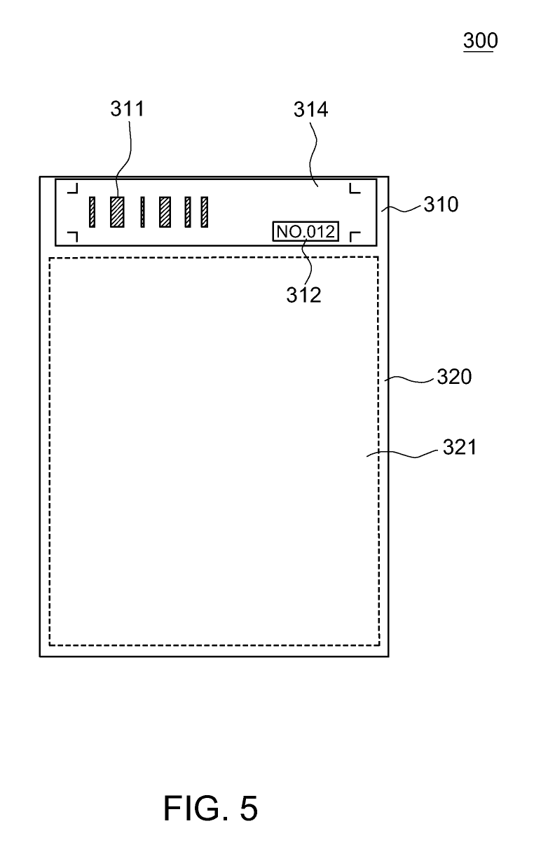

FIG. 5 shows a structural diagram of an auxiliary apparatus 300 according to an embodiment of the invention. The body of the auxiliary apparatus 300 is a scanned document, wherein a blank region at the front end of the scanned document is used as a determination region 310, most part of the rear end is a scan region 320, and the region marked by dotted lines within the scan region 320 is a to-be-scanned image region 321. The scanned document is a text document or an image document, wherein a label 314 with a specific image is pasted on the determination region 310 of the scanned document. The specific image constituted by a barcode 311 is printed on the label 314, and a code frame 312 denoting the serial number of the appended function is also printed on the determination region 310. The appended function being denoted is for executing optical character recognition (OCR) on the scan region 320.

As the scanning device begins scanning the scanned document, the determination region 310 is first scanned, and then the scan data of the specific image constituted by the barcode 311 is obtained. Next, the obtained scan data is compared with the data of the appended function predetermined in the scanning device to confirm that the scan data denotes the OCR function. Then, the scanning device automatically executes the appended function to scan and execute the OCR function on the to-be-scanned image region 321 of the scanned document and obtain the scan data of the scanned document on which the appended function is executed.

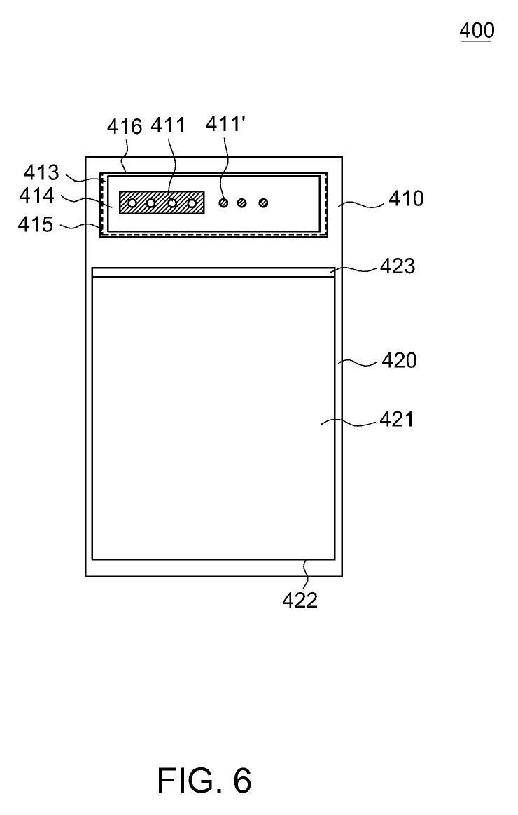

FIG. 6 shows a structural diagram of an auxiliary apparatus 400 according to an embodiment of the invention. The auxiliary apparatus 400 is a scanned document carrier, the body of the auxiliary apparatus 400 is, for example, a hard card, the front end of the auxiliary apparatus 400 is a determination region 410, and the rear end of the auxiliary apparatus 400 is a scan region 420. A transparent film 413 is fixed in the determination region 410, wherein the transparent film 413 has three edges including the edge 415 attached to the determination region 410 to constitute a bag whose one end has an opening 416. A label 414 is disposed in the bag, wherein a specific image having the white dots 411 and the black dots 411′ is printed on the label 414. The appended function denoted by the specific image is a function of adjusting the brightness and calibrating the ratio of a scanned image.

A transparent film 421 is disposed on the scan region 420 of the auxiliary apparatus. An edge 423 of the transparent film is adhered to the scan region 420 and can be detached relative to the edge 422, so that the scanned document can be placed and retained between the two edges 422 and 423. The scanning device first scans the determination region, and then automatically performs the subsequent scanning according to the appended function selected by the user.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A scanning method of automatically executing appended scanning or processing function of a scanning device, comprising:
loading a specific image which can be identified by a scanning module of the scanning device on a scanned document or a scanned document carrier, wherein an appended function denoted by the specific image is predetermined in a processing module of the scanning device; and
automatically executing the predetermined appended scanning function or processing function by the scanning device according to the scan data of the specific image as the scanning device scans the scanned document or the scanned document carrier.

2. The scanning method of automatically executing appended scanning function according to claim 1, further comprising:
allocating a determination region at a scan initial end of the scanned document or the scanned document carrier, wherein the specific image is located within the determination region, and the scanning module of the scanning device first scans the determination region, and then automatically executes the predetermined appended function according to the scan data of the specific image of the determination region.

3. The scanning method of automatically executing appended scanning function according to claim 1, wherein the specific image is a barcode type image, a black dot-formed image, a white dot-formed image, a black-and-white image, a color image, or a combined image of the above images that can be identified by the scanning device.

4. The scanning method of automatically executing appended scanning function according to claim 1, further comprising:
scanning a fixed number of lines first so as to obtain the scan data of the specific image, wherein the scan data comprises a combined data of the black and the white of the specific image or an interval data as the scanning device scans the specific image;
identifying the black and the white by a default value range defined on the scanning device; and
comparing the scan data of the specific image with the predetermined data by the scanning device to confirm the appended function denoted by the scan data of the specific image, and then executing the appended function for scanning or processing the scanned document.

5. The scanning method of automatically executing appended scanning function according to claim 1, wherein the predetermined appended function comprises the scanning function of confirming a scan boundary and a clarity level, and the image-processing function of calibrating and adjusting a scanned image.

6. A scanning method of automatically executing appended scanning function, comprising:
allocating a determination region at a scan initial end of a scanned document or scanned document carrier, wherein the determination region has a specific image which can be identified by a scanning device, the specific image is a barcode type image, a black dot-formed image, a white dot-formed image, a black-and-white image, a color image, or a combined image of the above images;
predetermining an appended scanning or processing function denoted by the scan data of the specific image in a processing module of the scanning device; and
firstly scanning the determination region by the scanning device to obtain the scan data of the specific image as the scanning device begins scanning, then automatically executing the appended scanning or processing function denoted by the scan data.

7. The scanning method of automatically executing appended scanning function according to claim 6, wherein the scan data of the specific image comprises a digit string, and the predetermined appended scanning function or processing function is recorded in the scanning device as an algorithm or a program.

8. An auxiliary apparatus of auto-executing appended scanning function, comprising:
a determination region, wherein a specific image, which can be identified by a scanning module of a scanning device is loaded on the determination region; and
a scan region used for disposing a to-be-scanned region of a scanned document.

9. The auxiliary apparatus of auto-executing appended scanning function according to claim 8, wherein the auxiliary apparatus is a planar structure, a scan initial end of the planar structure is the determination region, and the specific image is printed, placed or pasted on the determination region, and a scan end side of the scan region has a transparent scan storing portion used for fixing the scanned document.

10. The auxiliary apparatus of auto-executing appended scanning function according to claim 9, wherein the determination region has a transparent storage bag for retaining the specific image or a transparent sheet whose partial edge is fixed with the auxiliary apparatus.
